(19) United States
(12) Patent Application Publication
(10) Pub. No.: US 2009/0057006 A1
(43) Pub. Date: Mar. 5, 2009

(54) ELECTRONIC UNIT AND PRODUCTION METHOD OF THE SAME

(75) Inventors: Kazuyoshi Kishibata, Numazu-shi (JP); Kouji Sasaki, Numazu-shi (JP)

Correspondence Address: PEARNE & GORDON LLP, 1801 EAST 9TH STREET, SUITE 1200, CLEVELAND, OH, 44114-3108, US

(73) Assignee: Kokusan Denki Co., Ltd., Numazu-shi (JP)

(21) Appl. No.: 12/203,973

(22) Filed: Sep. 4, 2008

(30) Foreign Application Priority Data
Sep. 5, 2007 (JP) 2007-230612

(51) Int. Cl. H05K 3/30; H01L 23/28

(52) U.S. Cl. 174/521; 29/841

(57) ABSTRACT

A method of producing an electronic unit in which components are housed in a case and molded with resin, wherein an opening portion of the case housing the components of the unit is closed by a lid plate, the resin is poured into the case through the hole provided in the lid plate to fill the case with the resin while allowing air to be exhausted through a hole provided in a bottom wall portion of the case, with the lid plate of the case directed downward, then the resin in the case is discharged to the outside through the hole provided in the lid plate, and thus a resin mold layer that continuously covers entire surfaces of the components housed in the case and an inner surface of the case is formed with space in contact with the resin mold layer remaining in the case.

### TECHNICAL FIELD OF THE INVENTION

The present invention relates to an electronic unit in which components of the unit are housed in a case including a case body having an opening portion, and a lid plate that closes the opening portion of the case body, and a method of producing the electronic unit.

### PRIOR ART OF THE INVENTION

Two-wheel vehicles, ATVs (All terrain vehicles), automobiles, outboard engines, or the like include many electronic units such as an ignition device and a fuel injection device required for operating an engine, or a regulator that controls charging of a battery. Recreation vehicles sometimes include an electronic unit, which comprises a power unit including a power module including a converter that converts an AC output of a generator into a DC output and an inverter that converts the DC output of the converter into a power-frequency AC output, and a controller that controls the inverter, for allowing the output of the generator mounted to the engine to drive an external load. Further, vehicles including a motor as a drive source, such as electric motorcycles, electric vehicles or hybrid vehicles include an electronic control unit including a power module having a switch element that controls a driving current of the motor and a controller that controls the switch element of the power module.

An electronic unit included in a vehicle or an outboard engine needs weather proofing (mainly, water resistance) for preventing loss of function in driving in rain or being submerged in water. For the electronic unit to have weatherization, a structure has been generally adopted in which components are housed in a case and molded with resin filled in the case without any gap as disclosed in Japanese Patent Application Laid-Open Publication No. 2005-294702.

“Power module” herein refers to an electronic part having a construction in which components of a circuit that includes a power element through which a relatively large current flows, such as an MOSFET, a power transistor, a thyristor or a rectifier diode and serves a particular function are housed in a package. The circuit that serves a particular function includes, for example, a rectifier circuit, a regulator circuit, an inverter circuit, and a switch circuit that switches a polarity of a current to be supplied to a load.

When the structure is adopted in which resin is filled in the case housing the components without any gap as disclosed in Japanese Patent Application Laid-Open Publication No. 2005-294702, a large amount of resin is filled in the case, which inevitably increases a mass of the unit. Particularly, when the unit includes a power module, the size of the component is increased to increase a capacity of the case, which causes a problem of the increase in the mass caused by the increase in the amount of resin.

When components of a unit are connected by a metal connecting member in a case (for example, when a connecting pin pulled out of an electronic part is soldered to a circuit board), mold resin around the metal connecting member (connecting pin) has a high coefficient of thermal expansion, while the metal connecting member has a low coefficient of thermal expansion. Thus, when heat is generated from the components, stress in a direction of withdrawing the metal connecting member from the components occurs in resin provided between the components (for example, between an electronic part and a substrate) mechanically connected by the metal connecting member, which cause a high tensile force to be applied to the metal connecting member and a connecting portion thereof. The tensile force is removed when a temperature of the components decreases, and again applied when the temperature increases again. Thus, if a thermal cycle of the components is repeated, metal fatigue occurs in the metal connecting member and the connecting portion thereof (for example, the connecting pin and a soldered portion thereof), and finally, the metal connecting member or the connecting portion thereof may be damaged to lose the function of the unit Such a phenomenon noticeably occurs when components of a unit housed in a case include a power module that generates a large amount of heat, which reduces the life of the unit.

### SUMMARY OF THE INVENTION

An object of the present invention is to provide an electronic unit in which an amount of resin for molding components in a case is reduced to reduce a mass, and a production method of the electronic unit.

Another object of the present invention is to provide an electronic unit in which an amount of resin for molding components in a case is reduced to reduce a mass, and a possibility of damage to a metal connecting member or the like that connects between components caused by repetitions of a thermal cycle of the components is eliminated to increase the life, and a production method of the electronic unit.

The present invention is applied to an electronic unit in which components of the unit are housed in a case. In the present invention, a resin mold layer that continuously covers entire surfaces of the components housed in the case and an inner surface of the case is formed, and space in contact with the resin mold layer remains in the case.

Comprised as described above, the case is not filled with resin, thereby reducing the amount of use of mold resin to reduce a mass of the unit. The resin is not filled between the components housed in the case without any gap, and thus stress that occurs in the resin due to a difference in coefficient of thermal expansion between a metal connecting member such as a connecting pin that connects between the components and the resin is relieved to prevent damage to the metal connecting member and increase the life of the unit.

In one aspect of the present invention, the case includes a case body having an opening portion opposed to a bottom, and a lid plate that closes the opening portion of the case body, and at least the case body is made of metal. The components of the unit include a power module having a power element that generates heat, a busbar through which a main current that flows through the power element is passed, and a connecting pin through which control signals pass, the busbar and the connecting pin being pulled out of the power module, and a controller in which a component of a control portion that controls the power module is mounted on a circuit board. The power module is placed in contact with a bottom inner surface of the case body, and the controller is placed adjacent to the power module in a position closer to the opening portion of the case body than the power module, with the circuit board in parallel with the bottom inner surface of the case body. The connecting pin pulled out of the power module is soldered to the circuit board of the controller to connect between the power module and the controller. The resin mold layer is formed to also cover the connecting pin, and the space is also formed around the resin mold layer covering the connecting pin.

As described above, when the components include the power module, a large amount of heat is generated from the power module, and thus stress easily occurs in the resin due to a difference in coefficient of thermal expansion between the connecting pin and the resin. The present invention exerts a noticeable effect when applied to such an electronic unit.

The present invention also provides a method of producing an electronic unit in which components of the unit are housed in a case. In the production method according to the present invention, the components of the unit are housed in the case, and then a resin immersion step is performed by pouring liquid resin into the case and immersing the components in the case into the liquid resin. Then, a mold layer forming step is performed by discharging the liquid resin in the case to the outside, and thus forming a resin mold layer that continuously covers entire surfaces of the components housed in the case and an inner surface of the case with space in contact with the resin mold layer remaining in the case, and then a resin curing step of curing the resin that comprises the resin mold layer is performed.

In this case, the resin mold layer may be formed so as to cover the entire inner surface of the case, or only cover a portion of the inner surface of the case in contact with the resin when the components of the unit are immersed into the resin.

As described above, the liquid resin is poured into the case housing the components of the unit, the components in the case are immersed into the liquid resin, and then the liquid resin in the case is discharged to the outside. Then, in the case, only the resin that comprises the resin mold layer that continuously covers the entire surfaces of the components housed in the case and the inner surface of the case remains attached to the surfaces of the components and the inner surface of the case, and excess resin is discharged to the outside of the case. Thus, the electronic unit can be easily obtained in which the resin mold layer that continuously covers the entire surfaces of the components housed in the case and the inner surface of the case is formed, and the space in contact with the resin mold layer remains in the case.

### BRIEF DESCRIPTION OF THE DRAWINGS

The above and other objects and features of the invention will be apparent from the detailed description of the preferred embodiments of the invention, which is described and illustrated with reference to the accompanying drawings, in which;

FIG. 1 is an exploded perspective view of a first embodiment of an electronic unit according to the present invention;

FIG. 2 is a vertical sectional view showing a state before pouring of resin of the assembled unit in the first embodiment;

FIG. 3 is a vertical sectional view showing a state of the unit when resin is poured into a case in the first embodiment;

FIG. 4 is a vertical sectional view showing a state where the resin is being poured into the case in the first embodiment;

FIG. 5 is a vertical sectional view showing a state where pouring of the resin is completed in the first embodiment;

FIG. 6 is a vertical sectional view showing a state where the resin is discharged from the case to form a resin mold layer that covers surfaces of components and an inner surface of the case in the first embodiment;

FIG. 7 is a vertical sectional view showing a state where a hole provided in a lid plate of the case is sealed in the first embodiment;

FIG. 8 is a perspective view showing an appearance of a second embodiment of the present invention;

FIG. 9 is a vertical sectional view showing a state of a unit when resin is poured into a case in the second embodiment;

FIG. 10 is a vertical sectional view showing a state where pouring of the resin is completed in the second embodiment;

FIG. 11 is a vertical sectional view showing a state where the resin is discharged from the case to form a resin mold layer that covers surfaces of components and an inner surface of the case in the second embodiment;

FIG. 12 is a vertical sectional view showing a state where a hole provided in a lid plate of the case is sealed in the second embodiment; and

FIG. 13 is a vertical sectional view of essential portions for illustrating problems in forming a resin mold portion so as to fill a case in an electronic unit to which the present invention is directed.

### DETAILED DESCRIPTION OF THE PREFERRED EMBODIMENTS

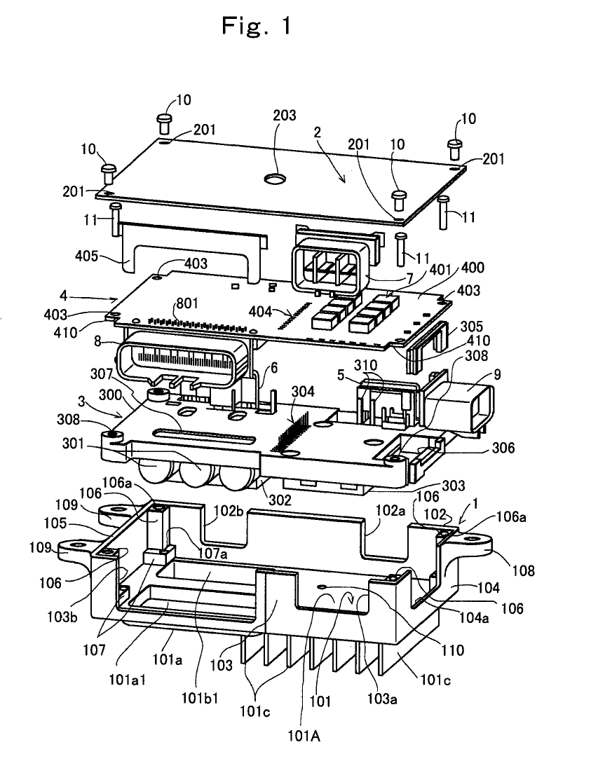

Now, preferred embodiments of the present invention will be described in detail with reference to the drawings. FIGS. 1 to 7 show a first embodiment of the present invention applied to an electronic unit that comprises a motor controller that drives and controls a motor as a drive source of an electric vehicle such as an electric starter.

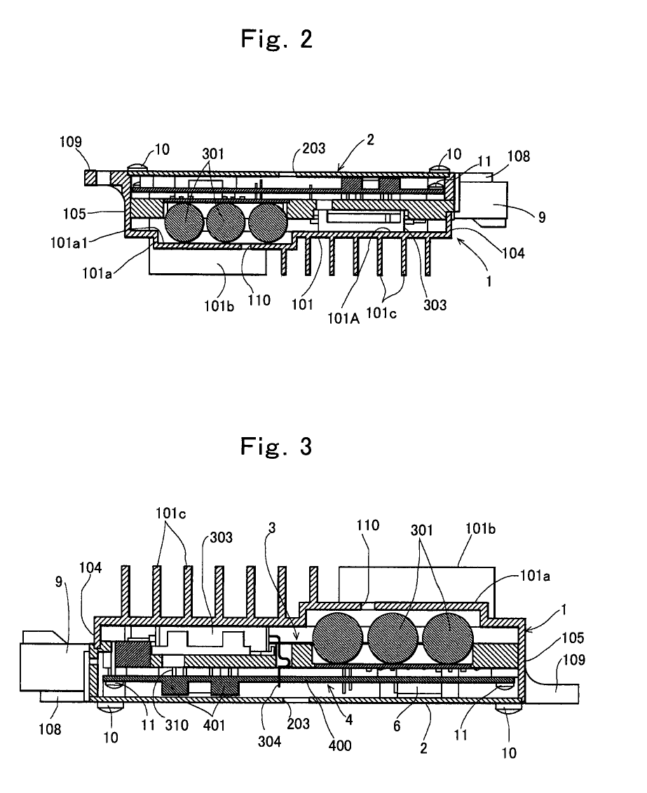

In FIGS. 1 and 2, reference numeral 1 denotes a box-shaped case body. The case body 1 has a rectangular bottom wall portion 101 and side walls 102 to 105 extending upward from four sides of the bottom wall portion 101, and has an opening portion on the side opposite to the bottom wall portion 101. Reference numeral 2 denotes a rectangular lid plate that closes the opening portion of the case body 1. In this example, a case that houses components of the electronic unit is comprised of the case body 1 and the lid plate 2. 3 denotes a power module, and 4 denotes a controller in which a component of a control portion that controls the power module 3 is mounted on a circuit board. 5 denotes a positive-side power supply connector connected to a positive terminal of a battery through an unshown electrical cord, and 6 denotes a negative-side power supply connector connected to a negative terminal of the battery through an unshown electrical cord. 7 denotes an auxiliary receptacle used for supplying electric power to an unshown auxiliary machine, 8 denotes a sensor signal input connector to which connectors mounted to ends of many signal wires connecting to various sensors are connected, and 9 denotes a receptacle to which a plug connecting to an armature coil of an unshown motor that is a drive source of the vehicle is connected.

In the bottom wall portion 101 of the case body 1, two expanded portions 101a and 101b that extend over substantially half in a longitudinal direction of the bottom wall portion 101 are formed in parallel with each other in a short side direction of the bottom wall portion 101, and recesses 101a1 and 101b1 formed inside the expanded portions open into the case body 1. The recess 101a1 is formed to be relatively shallow, and the recess 101b1 is formed to be deeper than the recess 101a1. In the embodiment, the recess 101a1 is used to house a capacitor 301 provided in the power module 3, and the recess 101b1 is used to house a relay 302 provided in the power module 3.

On an outer surface of the other half of the bottom wall portion 101 without the expanded portions 101a and 101b, many radiation fins 101c, 101c, . . . arranged at regular intervals in the longitudinal direction of the bottom wall portion 101 protrude. An inner surface of the bottom wall portion 101 at the portion with the radiation fins 101c, 101c, . . . on the outer surface is a flat part abutting surface 101A.

In the side wall 102 along one long side of the bottom wall portion 101 of the case body, a notch portion 102a to which the positive-side power supply connector 5 connected to the positive terminal of the battery is mounted, and a notch portion 102b to which the negative-side power supply connector 6 connected to the negative terminal of the battery is mounted are formed. In the side wall 103 along the other long side of the bottom wall portion 101, a notch portion 103a to which the auxiliary receptacle 7 is mounted, and a notch portion 103b to which the sensor signal input connector 8 is mounted are formed. In the side wall 104 extending upward from one short side of the bottom wall portion 101, a notch portion 104a is formed to which the receptacle 9 to which the plug connecting to the armature coil of the unshown motor is connected is mounted. In the embodiment, the motor is a three-phase brushless DC motor.

On an inside at four corners of the case body 1, boss portions 106 each having substantially the same height as the case body is formed. In each of the boss portions 106, a screw hole 106a is formed into which a screw 10 for fastening the lid plate 2 to the case body 1 is threaded. In portions closer to the bottom wall portion 101 at the four corners of the case body 1, low boss portions 107 are formed, and in each of the boss portions 107, a screw hole 107a is formed into which a screw 11 for fastening the controller 4 and the power module 3 to the case body 1 is threaded. On an outer side of a portion closer to an opening end of the side wall 104 of the case body 1, one bracket 108 used for securing the unit to a predetermined mounting position is provided. On an outer side of a portion closer to the opening end of the side wall 105 of the case body 1, two brackets 109 and 109 used for securing the unit to a predetermined mounting position are provided with a space therebetween in a width direction of the case body.

The lid plate 2 is formed of a rectangular metal plate that closes the opening portion of the case body 1, and mounting holes 201 are formed at four corners thereof. At substantially the center of the lid plate 2, a first hole 203 is provided through the lid plate. In the embodiment, a second hole 110 is formed through a portion provided with the part abutting surface 101A in the bottom wall portion of the case body 1. In the embodiment, as described later, in pouring resin into the case, the first hole 203 is used as a resin pouring port, and the second hole 110 is used as a vent hole. Thus, the first hole 203 is formed to have a larger diameter than the second hole 110.

The power module 3 includes a plate-shaped substrate 300 formed of a resin molded product. The substrate 300 is formed into a rectangular shape that can be inserted into the case body 1, and on a back surface of the substrate 300, a plurality of capacitors 301, a relay 302 that interrupts power when overcurrent flows, and an FET module 303 are mounted.

The FET module 303 is a module in which MOSFETs that comprise a three-phase bridge type inverter circuit that drives a three-phase brushless motor are housed in a package. The inverter circuit used for driving the three-phase brushless motor is a known one comprised of a three-phase bridge circuit having sides formed by MOSFETs. A surface of the FET module 3 on the side opposite to the substrate 300 is a radiating surface to which a radiation plate of an FET is thermally connected.

Positive-side and negative-side DC terminals of the inverter circuit comprised in the FET module 303 are connected to the connectors 5 and 6 secured to the substrate 300 through two busbars partly molded by the substrate 300 and held by the substrate. Three-phase AC terminals of the inverter circuit are connected to three-phase terminals of the receptacle 9 through three busbars partly molded by the substrate 300 and held by the substrate. The three-phase AC terminals of the inverter circuit are connected to the three-phase armature coils of the unshown motor through the unshown plug connected to the receptacle 9 and an electrical cord connected to the plug.

The capacitor 301 is connected across the DC terminals of the inverter circuit. Many connecting pins (signal wires) 304 and other connecting conductors 310 pulled out of the FET module 303 extend through the substrate 300 and are pulled out of a front surface thereof for providing drive signals to the MOSFETs that comprise the inverter circuit.

In a short side of the substrate 300 of the power module 3, a positioning portion 306 in which the receptacle 9 is fitted and positioned is provided. The receptacle 9 is fitted and positioned in the positioning portion 306, and secured to the substrate 300 by a Π-shaped fastener 305 fitted to a housing of the receptacle 9 being locked in a locking portion provided in the positioning portion 306. Similarly, the positive-side power supply connector 5 and the negative-side power supply connector 6 to which the positive terminal and the negative terminal of the battery are connected are mounted on the substrate 300. The substrate 300 also has a window 307 for easy filling of resin into the case. The sensor signal input connector 8 is used for providing signals required for controlling the motor such as output signals of a Hall sensor that detects a position of a rotor of the brushless motor to the controller 4. Mounting holes 308 that can be aligned with the screw holes 107a at the four corners of the case body 1 are formed through four corners of the substrate 300.

The power module 3 is housed in the case body with the back surface (the surface on which the capacitor 301, the relay 302 and the FET module 303 are mounted) of the substrate 300 facing the bottom surface of the case body 1. When the power module 3 is housed in the case body 1, the radiating surface of the FET module 303 is abutted against the part abutting surface 101A of the case body 1 and thermally connected to the bottom wall portion 101 of the case body 1, and the capacitor 301 and the relay 302 are inserted into the recesses 101a1 and 101b1, respectively. The positive-side power supply connector 5 and the negative-side power supply connector 6 are fitted in the notches 102a and 102b in the side wall 102 of the case body, and the receptacle 9 is fitted in the notch portion 104a provided in the side wall 104.

The controller 4 includes a circuit board 400 on which a component of the control portion that controls the power module 3 is mounted. The circuit board 400 includes an insulation substrate having a circuit pattern formed thereon, and an electronic part 401 such as a microprocessor that comprises the control portion is mounted on a front surface of the circuit board 400. On a back surface of the circuit board 400, the sensor signal input connector 8 is placed, and a lead terminal 801 pulled out of the connector 8 is soldered to the circuit pattern of the circuit board 400. At four corners of the circuit board 400, mounting holes 403 that can be aligned with the mounting holes 308 provided in the substrate 300 of the power module 3 are formed. Also at the four corners of the circuit board 400, notch portions 410 for relieving the substrate from the boss portions 106 at the four corners of the case body are provided.

The controller 4 is placed adjacent to the power module 3 in a position closer to the opening portion of the case body 1 than the power module 3, with the circuit board 400 in parallel with the bottom inner surface of the case body 1. Then, the many connecting pins 304 extending through the substrate of the power module 3 are inserted into through holes 404 provided in the circuit board 400, and the connecting pins 304 are soldered to the circuit pattern on the circuit board 400. The other connecting conductors 310 pulled out of the power module 3 are also soldered to the circuit pattern on the circuit board 400. The connector 8 is fitted and positioned in the notch portion 103b provided in the side wall 103 of the case body 1, and a gap between an opening edge of the notch portion 103b and the connector 8 is closed by a Π-shaped mounting bracket 405 fitted to the connector 8 from outside. The auxiliary receptacle 7 is fitted and mounted in the notch portion 103a in the side wall 103 of the case body 1. The auxiliary receptacle 7 is connected to the positive-side power supply connector 5 and the negative-side power supply connector 6 to which the positive terminal and the negative terminal of the battery are connected, via an unshown switch. FIG. 2 shows the unit thus assembled.

A fitted portion between each notch portion provided in the case body and the connector or the receptacle is held in a resin-liquid-tight manner by means such as tight fitting, bonding, or providing packing therebetween, so as to prevent resin from leaking from between the fitted portion between each notch portion and the connector or the receptacle when the liquid resin is poured into the case body.

As described above, after the power module 3 and the controller 4 are housed in the case body 1, the screws 11 are threaded into the screw holes 107a in the case body 1 through the mounting holes 403 at the four corners of the circuit board 400 of the controller 4 and the mounting holes 308 at the four corners of the substrate 300 of the power module 3 to fasten the power module 3 and the controller 4 to the case body 1. Then, the lid plate 2 is placed on the opening end of the case body 1, the screws 10 are threaded into the screw holes 106a in the case body 1 through the mounting holes 201 at the four corners of the lid plate 2 to fasten the lid plate 2 to the case body 1 and close the opening portion of the case body with the lid plate 2. An abutting portion between the opening end of the case body 1 and the lid plate 2 is comprised so that the opening portion of the case body 1 is closed in a resin-liquid-tight manner with the lid plate 2 fastened to the case body 1 as described above.

In the electronic unit according to the present invention, a resin mold layer that continuously covers entire surfaces of the components housed in the case and an inner surface of the case is formed, and space in contact with the resin mold layer remains in the case.

In a production method of the electronic unit according to the present invention, a step of housing the components of the unit in the case, a resin immersion step of pouring the liquid resin into the case housing the components and immersing the components in the case into the liquid resin, a mold layer forming step of discharging the liquid resin in the case to the outside, and thus forming the resin mold layer that continuously covers the entire surfaces of the components housed in the case and the inner surface of the case with the space in contact with the resin mold layer remaining in the case, and a resin curing step of curing the resin that comprises the resin mold layer are performed.

In this embodiment, the components (in the embodiment, the power module 3 and the controller 4) of the unit are housed in the case body 1, the opening portion of the case body 1 is closed by the lid plate 2, and then the liquid resin is poured into the case through the hole provided in the lid plate 2 or the case body 1. After the case is filled with the liquid resin, the liquid resin in the case is discharged to the outside, and thus the resin mold layer that continuously covers the entire surfaces of the components housed in the case and the inner surface of the case is formed with the space in contact with the resin mold layer remaining in the case, and then the resin in the case is cured.

In the embodiment, as described above, the first hole 203 and the second hole 110 are formed through the lid plate 2 of the case and the bottom wall portion 101 of the case body 1 facing the lid plate, the components of the unit are housed in the case body 1 and the opening portion of the case body is closed by the lid plate 2, and then the resin immersion step is performed, with one of the first hole 203 and the second hole 110 placed on an upper side and the other placed on a lower side, by pouring the liquid resin into the case through the hole on the lower side to fill the case with resin while allowing air to be exhausted through the hole on the upper side. After the case is filled with the liquid resin, the mold layer forming step is performed by discharging the liquid resin in the case to the outside through the hole on the lower side, and thus forming the resin mold layer that continuously covers the entire surfaces of the components housed in the case and the inner surface of the case with the space in contact with the resin mold layer remaining in the case, and then the resin curing step of curing the resin is performed.

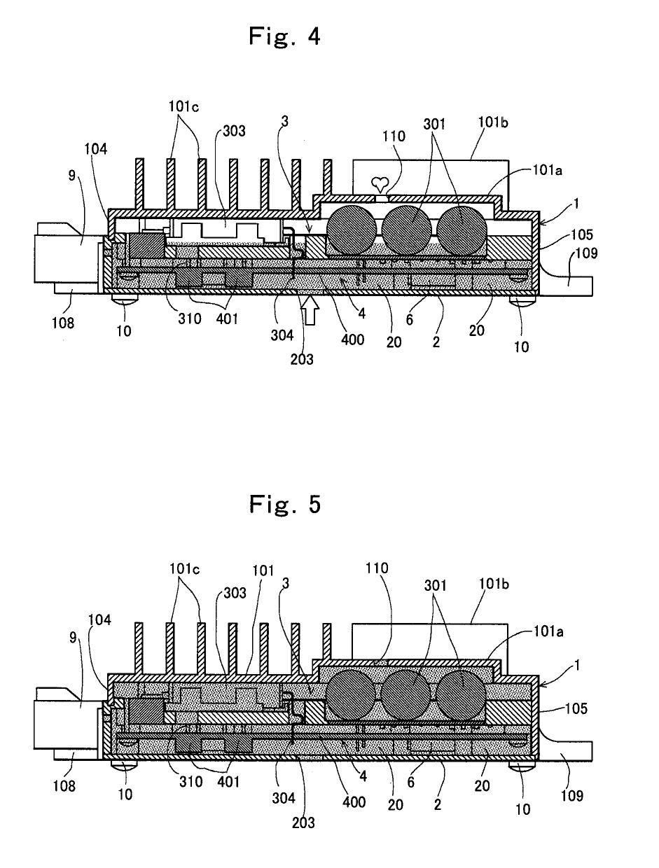

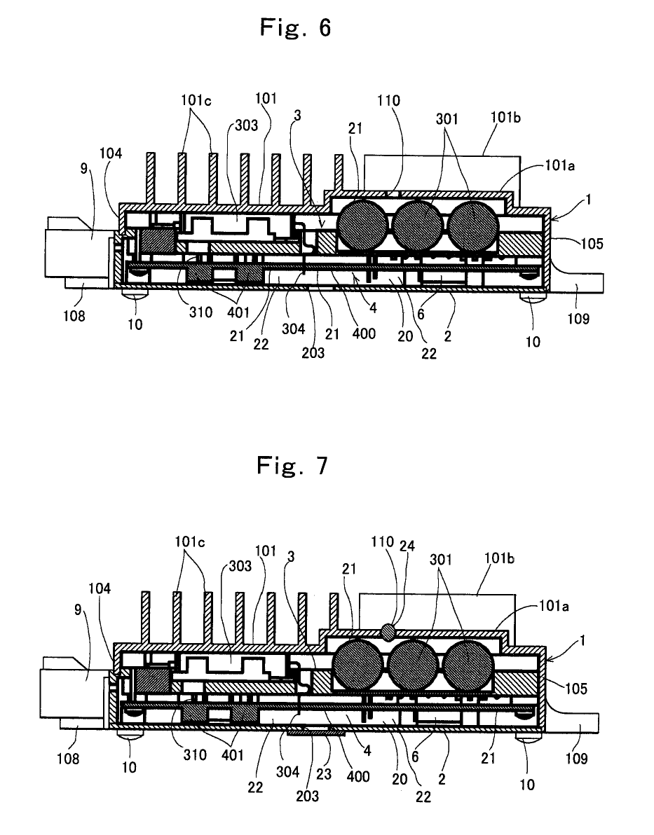

In the shown example, after the components of the unit are housed in the case body 1 and the opening portion of the case body 1 is closed by the lid plate 2, as shown in FIG. 3, the second hole 110 is directed upward (opened), and the first hole 203 is directed downward. In this state, a resin supply pipe (not shown) connected to a resin supply source is connected to the first hole 203 directed downward, air is exhausted through the second hole 110 directed upward, and as FIG. 4, the liquid resin 20 is gradually poured into the case through the first hole 203. After confirming that the case is filled with the liquid resin 20 and the second hole 110 is filled with the resin as shown in FIG. 5, the liquid resin in the case is discharged to the outside through the first hole 203 directed downward and recovered, and thus as shown in FIG. 6, the resin mold layer 21 that continuously covers the entire surfaces of the components housed in the case and the inner surface of the case is formed with the space 22 in contact with the resin mold layer 21 remaining in the case. Viscosity of the liquid resin is set so that the resin mold layer 21 formed after the resin is discharged from the case has a required thickness (a thickness required for insulation of the components of the unit and protection from water). If the liquid resin recovered from the case is uncured and maintains its viscosity (fluidity), the liquid resin can be reused by filtering or the like for removing impurities mixed therein.

After the resin mold layer 21 is formed as described above, the resin curing step of curing the resin that comprises the resin mold layer 21 is performed. When heat-curable resin is used as the resin that comprises the resin mold layer 21, the unit is heated in a furnace to cure the resin.

After the resin that comprises the resin mold layer is cured as described above, as shown in FIG. 7, a sheet 23 having breathability is bonded around the opening portion of the first hole 203 to liquid-tightly close the first hole 203, and the second hole 110 is liquid-tightly closed by a sealer 24 such as a stopper to complete the unit.

As described above, the opening portion of the case body 1 housing the components of the unit is closed by the lid plate 2, the liquid resin is poured into the case to fill the case with the liquid resin, and then the liquid resin in the case is discharged to the outside. Then, only the resin that comprises the resin mold layer that continuously covers the entire surfaces of the components housed in the case and the inner surface of the case remains in the case, and excess resin is discharged to the outside of the case. Thus, the electronic unit can be easily obtained in which the resin mold layer 21 that continuously covers the entire surfaces of the components housed in the case and the inner surface of the case is formed, and the space 22 in contact with the resin mold layer 21 remains in the case.

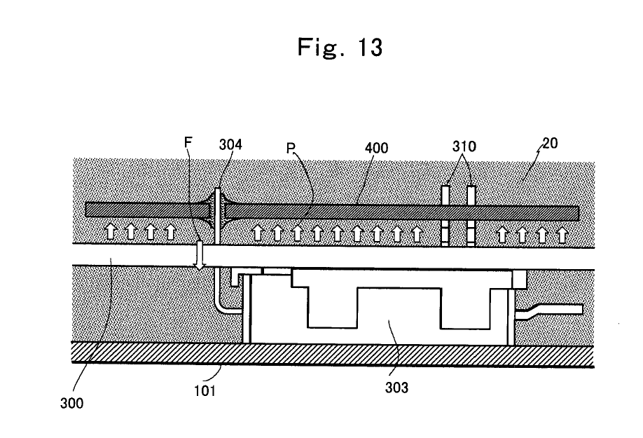

In the unit of the embodiment, it is supposed that resin is cured with the case filled with mold resin 20 as shown in FIG. 13. When the components of the unit are connected by a metal connecting members in the case, for example, when the metal connecting members such as the connecting pins 304 and the connecting conductors 310 pulled out of the electronic part of the power module are soldered to the circuit board 400 as described in the embodiment, the mold resin around the metal connecting members (304 and 310) has a high coefficient of thermal expansion, while the metal connecting members have a low coefficient of thermal expansion. Thus, if the case is filled with the resin, when heat is generated from the components, stress P in a direction of withdrawing the metal connecting members from the components occurs in resin provided between the components (for example, between the substrate 300 of the power module 3 and the circuit board 400 in the shown example) mechanically connected by the metal connecting members (304 and 310), which causes a high tensile force F to be applied to the metal connecting members and connecting portions (soldered portions) thereof. The tensile force is removed when a temperature of the components decreases, and again applied when the temperature increases again. Thus, if a thermal cycle of the components is repeated, metal fatigue occurs in the metal connecting members and the connecting portions thereof, and finally, the metal connecting members or the connecting portions thereof may be damaged to lose the function of the unit. Such a phenomenon noticeably occurs when components of the unit housed in the case include a power module that generates a large amount of heat, which reduces the life of the unit.

On the other hand, according to the present invention, the resin is not filled between the components housed in the case without any gap, and thus stress that occurs in the resin due to a difference in coefficient of thermal expansion between the metal connecting members such as the connecting pins that connect between the components and the resin is relieved to prevent damage to the metal connecting members and increase the life of the unit.

As in the embodiment, with the lid plate placed on the lower side, the resin in the case is discharged through the hole provided in the lid plate. Thus, the resin mold layer can be formed so as to reliably cover the abutting portion between the lid plate and the opening portion of the case body, and thus the abutting portion between the lid plate and the opening portion of the case body can be reliably sealed to increase water resistance of the unit.

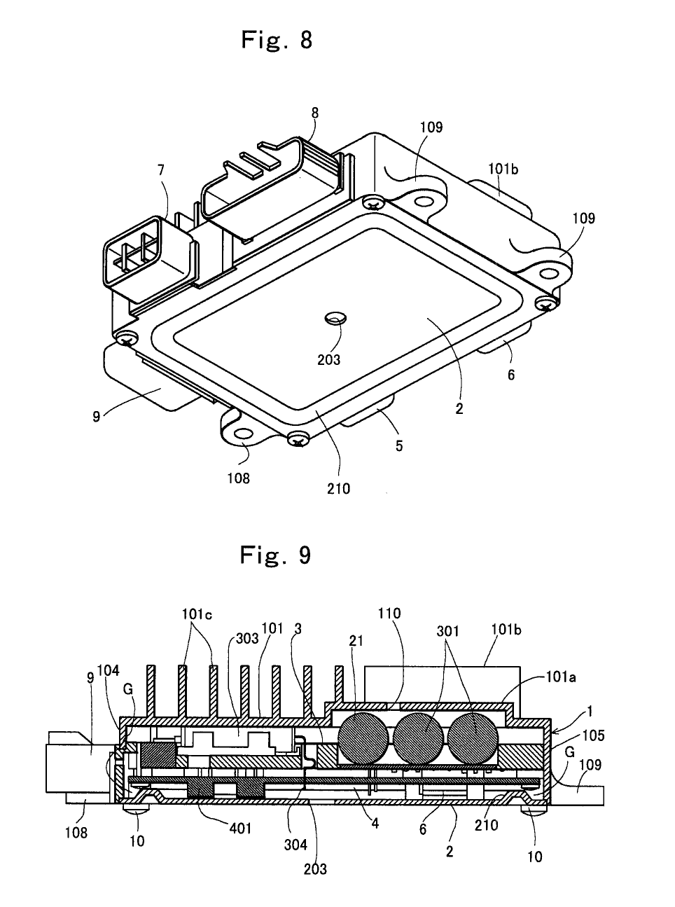

Next, with reference to FIGS. 8 to 12, a second embodiment of the present invention will be described. In the embodiment, the first hole 203 and the second hole 110 are formed through the lid plate 2 of the case and the bottom wall portion 101 of the case body 1 facing the lid plate, and as shown in FIGS. 8 and 9, a ridge 210 extending to form a closed loop along a side wall of the case body is formed in a position closer to a peripheral edge of the lid plate 2 (a position closer to the side wall of the case body 1), and a groove G that forms a closed loop is formed between the ridge 210 and a side wall inner surface near the opening portion of the case body 1. Other constructions of the unit are the same as in the first embodiment shown in FIGS. 1 to 7.

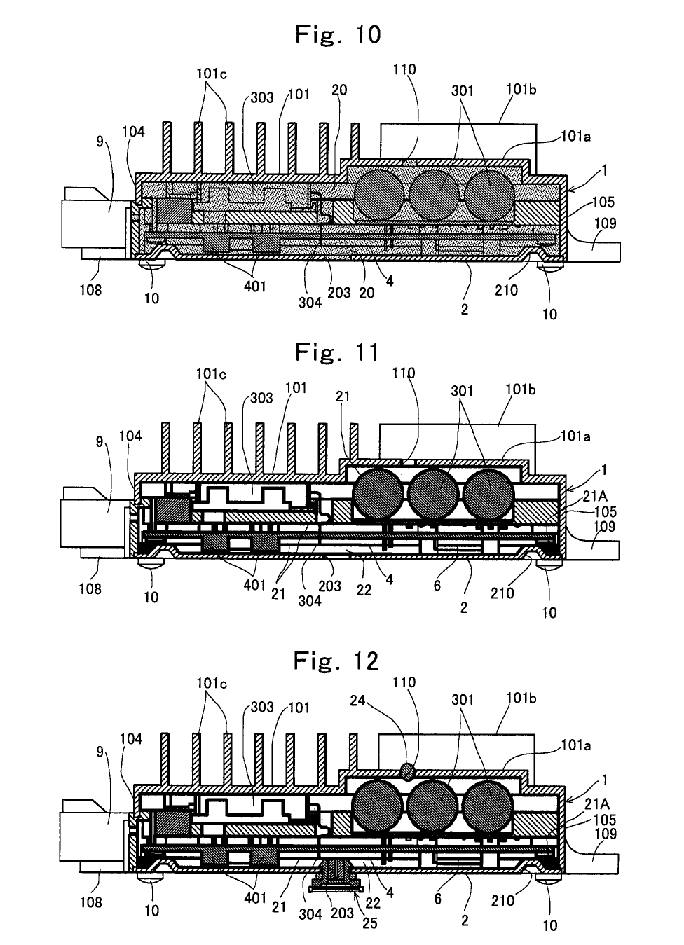

After the components of the unit are housed in the case body 1 and the opening portion of the case body is closed by the lid plate 2, as shown in FIG. 9, with the first hole 203 directed downward and the second hole 110 directed upward, the liquid resin 20 is poured into the case through the first hole 203 to fill the case with the liquid resin 20 as shown in FIG. 10. Then, the liquid resin 20 in the case is discharged to the outside through the first hole 203 directed downward, and thus the resin mold layer 21 that continuously covers the entire surfaces of the components housed in the case and the inner surface of the case is formed with the space 22 in contact with the resin mold layer 21 remaining in the case as shown in FIG. 11. At this time, resin 21A that fills the closed loop groove G formed between the ridge 210 on the lid plate and the side wall inner surface near the opening portion of the case body remains as it is. Then, in the embodiment, as shown in FIG. 12, the first hole 203 is closed by a waterproof stopper 25 having breathability, and the second hole 110 is liquid-tightly closed by the sealer 24 such as a stopper to complete the unit.

As described above, the ridge 210 extending along the side wall of the case body is formed in the position closer to the case body on the inner surface of the lid plate 2, thus the groove G that forms the closed loop is formed between the ridge and the side wall inner surface near the opening portion of the case body 1, and the resin 21A filled in the groove remains as it is. Thus, the resin 21A filled in the groove G can seal a joining portion between the lid plate 2 and the opening portion of the case body, thereby increasing sealing performance of the case to increase water resistance of the unit.

In the above described embodiments, the resin is poured into and recovered from the case with the lid plate 2 directed downward. However, in the production method according to the present invention, it is only necessary that after the components of the unit are housed in the case, the liquid resin is poured into the case, the components in the case are immersed into the liquid resin, then the liquid resin in the case is discharged to the outside, and thus the resin mold layer that continuously covers the entire surfaces of the components housed in the case and the inner surface of the case may be formed with the space in contact with the resin mold layer remaining in the case. The production method is not limited to the case where the resin is poured into and recovered from the case with the lid plate 2 directed downward as in the above described embodiments.

For example, it may be allowed that the second hole 110 is sized so that the resin can be poured and discharged therethrough, and as shown in FIG. 2, the resin is poured into and recovered from the case with the lid plate 2 of the case directed upward and the bottom wall portion 101 of the case body 1 directed downward.

It may be also allowed that both of the first hole 203 and the second hole 110 are sized so that the resin can be poured and discharged therethrough, and as shown in FIG. 2, the resin is poured into the case through the first hole 203 or the second hole 110 with the lid plate 2 of the case directed upward and the bottom wall portion 101 of the case body directed downward, and then as shown in FIG. 3, the resin is recovered from the case through the first hole 203 with the lid plate 2 directed downward.

As in the above described embodiments, when the liquid resin is poured into the case through the hole placed in the lower end of the case, a liquid level of the resin can be gradually increased in the case and the resin can be uniformly attached to the entire surfaces of the components in the case and the inner surface of the case, and thus the entire surfaces of the components in the case and the inner surface of the case can be covered with the resin without generating air bubbles.

After the case is filled with the liquid resin, the liquid resin in the case is discharged to the outside through the hole placed in the lower end of the case. Thus, excess resin other than the resin that comprises the resin mold layer that continuously covers the entire surfaces of the components housed in the case and the inner surface of the case can be easily discharged to the outside of the case.

As in the above described embodiments, the case is once filled with the resin when the liquid resin is poured into the case. Thus, the resin mold layer that covers the joining portion between the lid plate and the case body can be formed to increase sealing performance of the joining portion between the lid plate and the case body to increase water resistance. However, the present invention is not limited to the case where the case is once filled with the resin when the liquid resin is poured into the case. It is only necessary that the resin mold layer is formed to cover at least the entire surface of the components of the unit housed in the case and the inner surface of the case around the components. Thus, when there is a gap between an upper end of the case and upper ends of the components of the unit housed in the case, it may be allowed that the liquid resin is poured into the case body until the components of the unit are completely immersed into the liquid resin, then the resin in the case body is discharged to the outside, and the resin mold layer that continuously covers the entire surfaces of the components of the unit and the inner surface of the case around the components is formed.

In this case, it may be allowed that, with the lid plate of the case removed, the resin is poured into the case body from the opening portion of the case body 1, and the resin in the case body is discharged through the hole provided in the case body to form a resin mold portion. Specifically, it may be allowed that after the components of the unit are housed in the case body 1, the liquid resin is poured into the case body from the opening portion with the opening portion of the case body 1 directed upward, the components housed in the case body are immersed into the liquid resin, then the liquid resin in the case body is discharged to the outside through the hole 110 provided in the bottom wall portion of the case body 1, thus the resin mold layer that continuously covers the entire surfaces of the components housed in the case body and the inner surface of the case body is formed with the space in contact with the resin mold layer remaining in the case, and the case body is closed by the lid plate after or before the resin is cured.

In the above described method, when the resin that comprises the resin mold layer is cured before the case body is closed by the lid plate, light or electron beam can be applied to the resin in the case body, and thus light-curable resin or electron-beam-curable resin may be used.

When the resin mold layer cannot be formed in the abutting portion between the lid plate and the opening portion of the case body, such as when the liquid resin is poured into the case body until the components of the unit are completely immersed into the liquid resin, and then the resin in the case body is discharged to the outside to form the resin mold layer, packing is provided in the abutting portion between the lid plate 2 and the case body 1, or the lid plate 2 is bonded to the opening end of the case body 1, thereby ensuring liquid tightness of the abutting portion between the lid plate 2 and the case body 1.

In the production method of the electronic unit according to the present invention, it may be allowed that the first hole 203 and the second hole 110 are formed through the lid plate 2 of the case and the bottom wall portion 101 of the case body 1 facing the lid plate 2, the components of the unit are housed in the case body 1 and the opening portion of the case body is closed by the lid plate 2, then with one of the first hole 203 and the second hole 110 directed upward and the other directed downward, the liquid resin is poured into the case through the hole directed upward with the hole directed downward being closed to fill the case with the liquid resin, then the hole directed downward is opened to discharge the liquid resin in the case to the outside, thus the resin mold layer that continuously covers the entire surfaces of the components housed in the case and the inner surface of the case is formed with the space in contact with the resin mold layer remaining in the case, and then the resin is cured.

As described above, when one of the first hole 203 and the second hole 110 provided in the lid plate 2 of the case and the bottom wall portion 101 of the case body 1, respectively, is directed upward and the other is directed downward, and the liquid resin is poured into the case through the hole directed upward to fill the case with the liquid resin, it is preferable that a plurality of holes directed upward are provided, the liquid resin is poured into the case through one of the plurality of holes, and air in the case is exhausted through the other holes. For example, when the case is placed with the first hole 203 provided in the lid plate of the case being directed upward and the second hole 110 provided in the bottom wall portion of the case body being directed downward, the second hole 110 is closed, and the liquid resin is poured into the case through the first hole 203, it is preferable that a plurality of first holes 203 are provided in the lid plate 2, the resin is poured through one of the plurality of first holes and the other first holes are kept opened, and air in the case is exhausted through the opened first holes.

In the production method of the electronic unit according to the present invention, it may be allowed that after the opening portion of the case body housing the components of the unit is closed by the lid plate, liquid resin in an amount required and sufficient for forming the resin mold layer that continuously covers the entire surfaces of the components in the case and the inner surface of the case is poured into the case, and the case is rotated and/or reversed to form the resin mold layer.

For example, it may be allowed that the first hole 203 and the second hole 110 are formed through the lid plate 2 of the case and the bottom wall portion 101 of the case body 1 facing the lid plate, the components of the unit are housed in the case body 1 and the opening portion of the case body is closed by the lid plate 2, then air is exhausted from one of the first hole 203 and the second hole 110 and the liquid resin is poured into the case from the other, then the first hole 203 and the second hole 110 are closed and the case is rotated and/or reversed to bring the liquid resin into uniform contact with the components in the case and the inner surface of the case to form a resin mold portion.

In the above described method, when a larger amount of liquid resin is poured into the case, the case is rotated and/or reversed, then the first hole 203 and the second hole 110 are opened, excess liquid resin that does not attach to the surfaces of the components and the inner surface of the case is discharged through the first hole 203 or the second hole 110, and then the step of curing the resin is performed.

Also in the above described method, when the liquid resin in the amount required for forming the resin mold layer that continuously covers the entire surfaces of the components in the case and the inner surface of the case is poured into the case, the step of discharging the resin in the case can be omitted to shift to the step of curing the resin.

According to the above described method, the amount of resin poured into the case can be reduced, and even when the excess resin is recovered from the case, the amount of recovered resin can be reduced, thereby reducing cost.

Particularly in the above described method, when the liquid resin in the amount required for forming the resin mold layer that continuously covers the entire surfaces of the components in the case and the inner surface of the case is poured into the case, the step of discharging the resin in the case can be omitted to increase production efficiency.

In the above described methods, it is preferable that the liquid resin is poured into the case while vacuuming the case. When the resin is poured into the case while vacuuming the case, generation of air bubbles in the resin mold layer can be prevented, thereby preventing the air bubbles from reducing insulating performance of the resin mold layer.

In the above described embodiments, the MOSFETs are used as the power elements of the power module, but the present invention may be of course applied to the case where other power elements such as power transistors or thyristors are used.

In the above described embodiments, the two components: the power module and the controller are housed in the case, but the present invention may be applied to the case where more components are arranged hierarchically in the case (stacked or arranged in a depth direction of the case).

In the above described embodiments, the power module is housed in the case, but the present invention is not limited to the case where the power module is housed in the case, and may be applied to other electronic units that needs weatherization such as an ECU (electronic control unit) that controls an engine.

The preferred embodiments of the present invention have been described above, and the aspects of the present invention disclosed herein are summarized as described below.
(1) The present invention is applied to an electronic unit in which components of the unit are housed in a case. In the present invention, a resin mold layer that continuously covers entire surfaces of the components housed in the case and an inner surface of the case is formed, and space in contact with the resin mold layer remains in the case.

Comprised as described above, the case is not filled with resin, thereby reducing the amount of use of mold resin to reduce a mass of the unit. The resin is not filled between the components housed in the case without any gap, and thus stress that occurs in the resin due to a difference in coefficient of thermal expansion between a metal connecting member such as a connecting pin that connects between the components and the resin is relieved to prevent damage to the metal connecting member and increase the life of the unit.
(2) In one aspect of the present invention, the case includes a case body having an opening portion opposed to a bottom, and a lid plate that closes the opening portion of the case body, and at least the case body is made of metal. The components of the unit include a power module having a power element or elements that generates heat, a busbar through which a main current that flows through the power element(s) is passed, and a connecting pin through which control signals pass, the busbar and the connecting pin being pulled out of the power module, and a controller in which a component of a control portion that controls the power module is mounted on a circuit board. The power module is placed in contact with a bottom inner surface of the case body, and the controller is placed adjacent to the power module in a position closer to the opening portion of the case body than the power module, with the circuit board in parallel with the bottom inner surface of the case body. The connecting pin pulled out of the power module is soldered to the circuit board of the controller to connect between the power module and the controller. The resin mold layer is formed to also cover the connecting pin, and the space is also formed around the resin mold layer covering the connecting pin.

As described above, when the components include the power module, a large amount of heat is generated from the power module, and thus stress easily occurs in the resin due to a difference in coefficient of thermal expansion between the connecting pin and the resin. The present invention exerts a noticeable effect when applied to such an electronic unit.
(3) In a preferred aspect of the present invention, a ridge extending to form a closed loop along a side wall of the case body is formed in a position closer to a peripheral edge of the lid plate in a protruding manner into the case body, a groove that forms a closed loop is formed between the ridge and a side wall inner surface near the opening portion of the case body, the resin is filled in the closed loop groove to seal a joining portion between the lid plate and the opening portion of the case body.

As described above, the ridge extending to form the closed loop along the side wall of the case body is formed in the position closer to the peripheral edge of the lid plate in the protruding manner into the case body, thus the groove that forms the closed loop is formed between the ridge and the side wall inner surface near the opening portion of the case body, and the resin is filled in the groove. The resin filled in the groove can seal the joining portion between the lid plate and the opening portion of the case body, and thus the case can be sealed to increase water resistance of the unit.
(4) The present invention also provides a method of producing an electronic unit in which components of the unit are housed in a case that includes a case body having an opening portion and a lid plate that closes the opening portion of the case body.

In the production method according to the present invention, a step of housing the components of the unit in the case is performed, and then a resin immersion step is performed by pouring liquid resin into the case and immersing the components in the case into the liquid resin. Then, a mold layer forming step is performed by discharging the liquid resin in the case to the outside, and thus forming a resin mold layer that continuously covers entire surfaces of the components housed in the case and an inner surface of the case with space in contact with the resin mold layer remaining in the case, and then a resin curing step of curing the resin that comprises the resin mold layer is performed.

In this case, the resin mold layer may be formed so as to cover the entire inner surface of the case, or only cover a portion of the inner surface of the case in contact with the resin when the components of the unit are immersed into the resin.

As described above, the liquid resin is poured into the case housing the components of the unit, the components in the case are immersed into the liquid resin, and then the liquid resin in the case is discharged to the outside. Then, in the case, only the resin that comprises the resin mold layer that continuously covers the entire surfaces of the components housed in the case and the inner surface of the case remains attached to the surfaces of the components and the inner surface of the case, and excess resin is discharged to the outside of the case. Thus, the electronic unit can be easily obtained in which the resin mold layer that continuously covers the entire surfaces of the components housed in the case and the inner surface of the case is formed, and the space in contact with the resin mold layer remains in the case.

To form the resin mold layer so as to cover the surfaces of the components of the unit and the entire inner surface of the case, for example, it is only necessary that the liquid resin is poured into the case so as to fill the case, and then the excess liquid resin is discharged and recovered from the case.

If the resin recovered from the case is uncured and maintains its fluidity, the liquid resin can be reused by filtering or the like for removing impurities mixed therein. The recovered resin can be reused to reduce cost.
(5) In a preferred aspect of the production method according to the present invention, a case including a case body having an opening portion and a lid plate that closes the opening portion of the case body is used. After the components of the unit are housed in the case body and the opening portion of the case body is closed by the lid plate, then the resin immersion step is performed by pouring the liquid resin into the case through the hole provided in the lid plate or the case body to fill the case with the liquid resin, and then the mold layer forming step is performed by discharging the liquid resin in the case to the outside, and thus forming the resin mold layer that continuously covers the entire surfaces of the components housed in the case and the inner surface of the case with the space in contact with the resin mold layer remaining in the case. Then, the resin curing step of curing the resin that comprises the resin mold layer is performed.

As described above, after the opening portion of the case body housing the components of the unit is closed by the lid plate, the liquid resin is poured into the case through the hole provided in the lid plate or the case body to fill the case with the liquid resin, and then the liquid resin in the case is discharged to the outside. Then, only the resin that comprises the resin mold layer that continuously covers the entire surfaces of the components housed in the case and the inner surface of the case remains in the case, and excess resin is discharged to the outside of the case. Thus, the electronic unit can be easily obtained in which the resin mold layer that continuously covers the entire surfaces of the components housed in the case and the inner surface of the case is formed, and the space in contact with the resin mold layer remains in the case.
(6) In a preferred aspect of the present invention, a first hole and a second hole are formed through the lid plate of the case and the bottom wall portion of the case body facing the lid plate, the components of the unit are housed in the case body and the opening portion of the case body is closed by the lid plate, and then the resin immersion step is performed, with one of the first hole and the second hole directed upward and the other directed downward, by pouring the liquid resin into the case through the hole directed downward to fill the case with the liquid resin while allowing air to be exhausted through the hole directed upward. Then, the mold layer forming step is performed by discharging the liquid resin in the case to the outside through the hole directed downward, and thus forming the resin mold layer that continuously covers the entire surfaces of the components housed in the case and the inner surface of the case with the space in contact with the resin mold layer remaining in the case, and then the resin curing step of curing the resin that comprises the resin mold layer is performed.

As described above, when the liquid resin is poured into the case through the hole directed downward, a liquid level of the resin can be gradually increased in the case and the resin can be uniformly attached to the entire surfaces of the components in the case and the inner surface of the case, and thus the entire surfaces of the components in the case and the inner surface of the case can be covered with the resin. After the case is filled with the liquid resin, the liquid resin in the case is discharged to the outside through the hole placed on the lower side, and thus excess resin other than the resin that comprises the resin mold layer that continuously covers the entire surfaces of the components housed in the case and the inner surface of the case can be discharged to the outside of the case. The resin discharged to the outside of the case can be recovered and reused. As described above, the liquid resin is poured into the case through the hole directed downward, and thus the step of pouring the resin into the case to the step of discharging the resin can be performed without changing the position of the case, thereby simplifying the step of forming the resin mold layer.
(7) In a preferred aspect of the present invention, the first hole and the second hole are formed through the lid plate of the case and the bottom wall portion of the case body facing the lid plate, the components of the unit are housed in the case body and the opening portion of the case body is closed by the lid plate, and then the resin immersion step is performed, with one of the first hole and the second hole directed upward and the other directed downward, by pouring the liquid resin into the case through the hole directed upward with the hole directed downward being closed to fill the case with the liquid resin. Then, the mold layer forming step is performed by opening the hole directed downward and discharging the liquid resin in the case to the outside, and thus forming the resin mold layer that continuously covers the entire surfaces of the components housed in the case and the inner surface of the case with the space in contact with the resin mold layer remaining in the case, and the resin curing step of curing the resin that comprises the resin mold layer is performed.

As described above, with the first hole provided in the lid plate being directed downward, the resin is poured into and discharged from the case through the first hole. Thus, finally, a resin mold portion that covers a joining portion between the lid and the opening portion of the case body can be formed to seal the joining portion between the lid and the opening portion of the case body.
(8) In another preferred aspect of the present invention, the first hole and the second hole are formed through the lid plate of the case and the bottom wall portion of the case body facing the lid plate, the components of the unit are housed in the case body and the opening portion of the case body is closed by the lid plate, and the resin immersion step is performed by pouring the liquid resin into the case through the other while allowing air to be exhausted through one of the first hole and the second hole, and then closing the first hole and the second hole and rotating and/or reversing the case to bring the liquid resin into uniform contact with the components in the case. Then, the mold layer forming step is performed by opening the first hole and the second hole and discharging excess liquid resin that does not attach to the surfaces of the components through the first hole or the second hole, and thus forming the resin mold layer that continuously covers the entire surfaces of the components housed in the case and the inner surface of the case with the space in contact with the resin mold layer remaining in the case, and then the resin curing step of curing the resin that comprises the resin mold layer is performed.

According to the above described method, the amount of resin poured into the case can be reduced, and the amount of resin recovered from the case can be reduced. Thus, when the resin recovered from the case is reused, the amount of reused resin can be reduced to simplify cleaning in reusing the resin.
(9) In a further preferred aspect of the present invention, the first hole and the second hole are formed through the lid plate of the case and the bottom wall portion of the case body facing the lid plate, a ridge extending to form a closed loop along a side wall of the case body is formed in a position closer to a peripheral edge of the lid plate in a protruding manner into the case body, a groove that forms a closed loop is formed between the ridge and a side wall inner surface near the opening portion of the case body, the components of the unit are housed in the case body and the opening portion of the case body is closed by the lid plate, and then the resin immersion step is performed by pouring the liquid resin into the case through the first hole or the second hole to fill the case with the liquid resin. Then, the mold layer forming step is performed, with the first hole directed downward, by discharging the liquid resin in the case to the outside through the first hole, and thus forming the resin mold layer that continuously covers the entire surfaces of the components housed in the case and the inner surface of the case and a resin layer that fills the groove with the space in contact with the resin mold layer remaining in the case, and then the resin curing step of curing the resin that comprises the resin mold layer is performed.

According to the above described method, the resin can be filled in the closed loop groove formed along the side wall inner surface near the opening portion of the case body, and thus the joining portion between the lid plate and the opening portion of the case body can be reliably sealed by the resin to increase water resistance of the unit.
(10) In the above described methods, it is preferable that the liquid resin is poured into the case while vacuuming the case.

When the resin is poured into the case while vacuuming the case, generation of air bubbles in the resin mold layer can be prevented, thereby preventing the air bubbles from reducing insulating performance of the resin mold layer.
(11) In a further preferred aspect of the present invention, the resin immersion step is performed, after the components of the unit are housed in the case body, by pouring the liquid resin into the case body from the opening portion with the opening portion of the case body directed upward and immersing the components housed in the case body into the liquid resin, and then the mold layer forming step is performed by discharging the liquid resin in the case body to the outside through the hole provided in the bottom wall portion of the case body, and thus forming the resin mold layer that continuously covers the entire surfaces of the components housed in the case body and the inner surface of the case body with the space in contact with the resin mold layer remaining in the case. Then, the resin curing step of curing the resin is performed. The case body is closed by the lid plate after or before the resin is cured.

Comprised as described above, there is no need for providing a hole in the lid, and thus the step of sealing the hole provided in the lid can be omitted. The resin can be cured with the lid opened, and thus light-curable resin or electron-beam-curable resin may be used as the resin that comprises the mold resin layer besides the heat-curable resin.
(12) In a further preferred aspect of the present invention, components of a unit are housed in a case body, and a mold layer forming step is performed by pouring, into the case body, liquid resin in an amount required for forming a resin mold layer that continuously covers entire surfaces of the components in the case and an inner surface of the case, then rotating and/or reversing the case with the opening portion of the case body closed by the lid plate to bring the liquid resin into uniform contact with the components in the case, and forming the resin mold layer that continuously covers the entire surfaces of the components housed in the case and the inner surface of the case with space in contact with the resin mold layer remaining in the case, and then a resin curing step of curing the resin that comprises the resin mold layer is performed.

According to the above described method, the step of discharging the resin in the case can be omitted to increase production efficiency.
(13) In the above described production methods, the components of the unit include a power module having a power element that generates heat, a busbar through which a main current that flows through the power element is passed, and a connecting pin through which control signals pass, the busbar and the connecting pin being pulled out of the power module, and a controller in which a component of a control portion that controls the power module is mounted on a circuit board. In this case, the power module is placed in contact with a bottom inner surface of the case body, and the controller is placed adjacent to the power module in a position closer to the opening portion of the case body than the power module, with the circuit board in parallel with the bottom inner surface of the case body. The connecting pin pulled out of the power module is soldered to the circuit board of the controller to connect between the power module and the controller. The resin mold layer is formed to also cover the connecting pin, and the space is also formed around the resin mold layer covering the connecting pin.

If the production method according to the present invention is applied to the unit including the components having the above described construction, the amount of mold resin can be reduced to reduce a mass. Also, stress that occurs in the resin due to a difference in coefficient of thermal expansion between the resin and a metal connecting member such as a connecting pin that connects the components is relieved to prevent damage to the metal connecting member.

Although the preferred embodiments of the invention have been described and illustrated with reference to the accompanying drawings, it will be understood by those skilled in the art that there are by way of examples, and that various changes and modifications may be made without departing from the spirit and scope of the invention, which is defined only to the appended claims.

What is claimed is:

1. An electronic unit in which components of the unit are housed in a case, wherein a resin mold layer that continuously covers entire surfaces of the components housed in said case and an inner surface of said case is formed, and space in contact with said resin mold layer remains in said case.

2. The electronic unit according to claim 1, wherein said case includes a case body having an opening portion in a position opposed to a bottom, and a lid plate that closes the opening portion of said case body, and at least said case body is made of metal,
the components of said unit include a power module having a power element or elements that generate heat, a busbar through which a main current that flows through said power element(s) is passed, and a connecting pin through which control signals pass, said busbar and said connecting pin being pulled out of said power module, and a controller in which a component of a control portion that controls said power module is mounted on a circuit board,
said power module is placed in contact with a bottom inner surface of said case body,
said controller is placed adjacent to said power module in a position closer to the opening portion of said case body than said power module, with said circuit board in parallel with the bottom inner surface of said case body,
the connecting pin pulled out of said power module is soldered to the circuit board of said controller to connect between said power module and said controller, and
said resin mold layer is formed to also cover said connecting pin, and said space is also formed around the resin mold layer covering said connecting pin.

3. The electronic unit according to claim 2, wherein a ridge extending to form a closed loop along a side wall of said case body is formed in a position closer to a peripheral edge of said lid plate in a protruding manner into said case body, a groove that forms a closed loop is formed between said ridge and a side wall inner surface near the opening portion of said case body, the resin is filled in said closed loop groove to seal a joining portion between said lid plate and the opening portion of the case body.

4. A method of producing an electronic unit in which components of the unit are housed in a case that includes a case body having an opening portion and a lid plate that closes the opening portion of said case body, comprising:
a step of housing the components of the unit in said case;
a resin immersion step of pouring liquid resin into the case housing said components and immersing the components in said case into the liquid resin;
a mold layer forming step of discharging the liquid resin in said case, and thus forming a resin mold layer that continuously covers entire surfaces of the components housed in said case and an inner surface of said case with space in contact with said resin mold layer remaining in said case; and
a resin curing step of curing the resin that comprises said resin mold layer.

5. The method of producing an electronic unit according to claim 4, wherein said resin immersion step is performed, after the opening portion of the case body housing the components of said unit is closed by the lid plate, by pouring the liquid resin into said case through the hole provided in said lid plate or said case body to fill said case with the liquid resin.

6. The method of producing an electronic unit according to claim 5, wherein a first hole and a second hole are formed through the lid plate of said case and the bottom wall portion of said case body facing said lid plate, respectively,
said resin immersion step is performed, with one of said first hole and said second hole directed upward and the other directed downward, by pouring the liquid resin into said case through the hole directed downward to fill said case with the liquid resin while allowing air to be exhausted through the hole directed upward, and
said mold layer forming step is performed by discharging the liquid resin in said case to the outside through the hole directed downward.

7. The method of producing an electronic unit according to claim 5, wherein the first hole and the second hole are formed through the lid plate of said case and the bottom wall portion of said case body facing said lid plate, respectively,
said resin immersion step is performed, with one of said first hole and said second hole directed upward the other directed downward, by pouring the liquid resin into said case through the hole directed upward with the hole directed downward being closed to fill said case with the liquid resin, and
said mold layer forming step is performed by opening said hole directed downward and discharging the liquid resin in the case to the outside.

8. The method of producing an electronic unit according to claim 5, wherein the first hole and the second hole are formed through the lid plate of said case and the bottom wall portion of said case body facing said lid plate, respectively,
said resin immersion step is performed by pouring the liquid resin into said case through the other while allowing air to be exhausted through one of said first hole and said second hole, and then closing said first hole and said second hole and rotating and/or reversing said case to bring the liquid resin into uniform contact with the components in said case, and
said mold layer forming step is performed by opening said first hole and said second hole and discharging excess liquid resin that does not attach to the surfaces of said components through said first hole or said second hole.

9. The method of producing an electronic unit according to claim 6, wherein a ridge extending to form a closed loop along a side wall of said case body is formed in a position closer to a peripheral edge of said lid plate in a protruding manner into said case body, a groove that forms a closed loop is formed between said ridge and a side wall inner surface near the opening portion of said case body,
said resin immersion step is performed by pouring the liquid resin into said case through said first hole or said second hole to fill said case with the liquid resin, and
said mold layer forming step is performed, with said first hole directed downward, by discharging the liquid resin in said case to the outside through said first hole.

10. The method of producing an electronic unit according to claim 4, wherein the liquid resin is poured into said case while vacuuming said case.

11. The method of producing an electronic unit according to claim 4, wherein said resin immersion step is performed, after the components of the unit are housed in said case body, by pouring the liquid resin into said case body from said opening portion and immersing the components housed in said case body into the liquid resin with the opening portion of said case body directed upward, and
said mold layer forming step is performed by discharging the liquid resin in said case body to the outside through the hole provided in the bottom wall portion of said case body.

12. A method of producing an electronic unit in which components of the unit are housed in a case that includes a case body having an opening portion and a lid plate that closes the opening portion of said case body, comprising:
a step of housing the components of the unit in said case;
a mold layer forming step of pouring, into said case body, liquid resin only in an amount required for forming a resin mold layer that continuously covers entire surfaces of the components in said case and an inner surface of the case, then rotating and/or reversing said case with the opening portion of said case body closed by the lid plate to bring the liquid resin into uniform contact with the components in the case, and forming the resin mold layer that continuously covers the entire surfaces of the components housed in the case and the inner surface of the case with space in contact with the resin mold layer remaining in the case, and
a resin curing step of curing the resin that comprises said resin mold layer.
